(19) United States
(12) Patent Application Publication
(10) Pub. No.: US 2025/0273519 A1
(43) Pub. Date: Aug. 28, 2025

(54) SYSTEMS AND METHODS FOR PROCESSING SEMICONDUCTOR WAFERS USING NEAR EDGE REGION ROUNDNESS

(71) Applicant: GlobalWafers Co., Ltd., Hsinchu (TW)

(72) Inventors: YungHsing Chu, Hsinchu (TW); TaeHyeong Kim, PyeongTaek (KR); Jing Ru Hong, Zhubei City (TW)

(21) Appl. No.: 19/062,821

(22) Filed: Feb. 25, 2025

Related U.S. Application Data
(60) Provisional application No. 63/557,914, filed on Feb. 26, 2024.

(51) Int. Cl. H01L 21/66; G01N 21/88; G01N 21/95; H01L 21/67

(52) U.S. Cl. CPC H01L 22/12; G01N 21/8851; G01N 21/9503; H01L 21/67092; H01L 22/26

(57) ABSTRACT

A computer device for analyzing a processed product includes at least one processor in communication with at least one memory device. The at least one processor is programmed to: a) receive scan data of a first inspection of a first product being assembled after the first product has been processed by a tool; b) determine an edge profile for the product based upon the scan data; c) determine a center point for the edge profile; d) generate a best fit circle based upon the edge profile and the center point; e) calculate a NER radius for the first product based upon the best fit circle; and f) adjust operation of the tool based upon the NER radius.

### CROSS REFERENCE TO RELATED APPLICATIONS

This application claims priority to U.S. Provisional Application No. 63/557,914, filed Feb. 26, 2024, which is hereby incorporated by reference in its entirety.

### TECHNICAL FIELD

The field of the disclosure relates generally to processing of semiconductor wafers and, more particularly, to systems and methods for processing semiconductor wafers using near edge shape roundness parameters.

### BACKGROUND

As semiconductor wafer yield expectations increase, wafer near edge shape or profile has increasing effect on semiconductor device yield such as lithography process, in-process layers peeling, and edge flake defects. A smooth transition from the semiconductor wafer top surface to the wafer bevel is needed to improve device yield.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

The present disclosure relates to methods for determining and using near edge region rounding parameters such as NER radius and theta angle. In one aspect, a computer device for analyzing a processed product includes at least one processor (or “the processor) in communication with at least one memory device. The processor is programmed to a) receive scan data of a first inspection of a first product being assembled after the first product has been processed by a tool; b) determine an edge profile for the product based upon the scan data; c) determine a center point for the edge profile; d) generate a best fit circle based upon the edge profile and the center point; e) calculate a NER radius for the first product based upon the best fit circle; and f) adjust operation of the tool based upon the NER radius. The computer device may have additional, less, or alternate functionalities, including those discussed herein.

In another aspect, a method for analyzing a processed product is implemented by a computer device including at least one processor (or “the processor) in communication with at least one memory device. The method includes a) receiving scan data of a first inspection of a first product being assembled after the first product has been processed by a tool; b) determining an edge profile for the product based upon the scan data; c) determining a center point for the edge profile; d) generating a best fit circle based upon the edge profile and the center point; e) calculating a NER radius for the first product based upon the best fit circle; and f) adjusting operation of the tool based upon the NER radius. The method may have additional, less, or alternate functionalities, including those discussed herein.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

The Figures described below depict various aspects of the systems and methods disclosed. It should be understood that each Figure depicts an embodiment of a particular aspect of the disclosed systems and methods, and that each of the Figures is intended to accord with a possible embodiment thereof. Further, wherever possible, the following description refers to the reference numerals included in the following Figures, in which features depicted in multiple Figures are designated with consistent reference numerals. There are shown in the drawings arrangements presently discussed, it being understood, however, that the present embodiments are not limited to the precise arrangements.

FIG. 1 is a flowchart of a process for processing a wafer using a polished wafer geometry metric.

FIG. 2 is a flowchart of a process for processing a wafer using a front-end processed wafer geometry metric.

FIG. 3 is a flowchart of a process of wafer sampling to determine NER (near edge region) roundness.

FIG. 4 illustrates the near edge transition zone and the NER roundness quantitative analysis method.

FIG. 5 shows a method calculating NER values of the transition zone of a front-end processed wafer is shown.

FIG. 6 shows a method for determining a NER metric for a front-end processed wafer is described.

FIG. 7 shows an example block diagram of a system for processing a wafer using a front-end processed wafer geometry metric in accordance with the present disclosure.

FIG. 8 is a graph of the moving average height profile with the arc center being the max height between raw and moving average profiles.

FIG. 9 is a graph of the 2nd derivative of the 5th polynomial fitting profile.

FIG. 10 is a NER profile produced by the methods described herein.

FIG. 11 is a graph showing a sharp transition between top surface to bevel and a small NER radius and theta.

FIG. 12 is a graph of median transition with middle NER radius and theta.

FIG. 13 is a smooth transition with large NER radius and theta.

Corresponding reference characters indicate corresponding parts throughout the drawings.

### DETAILED DESCRIPTION

The present embodiments may relate to, inter alia, systems and methods for processing semiconductor wafers. For example, the systems and methods disclose a system for processing semiconductor wafers using near edge shape roundness parameters.

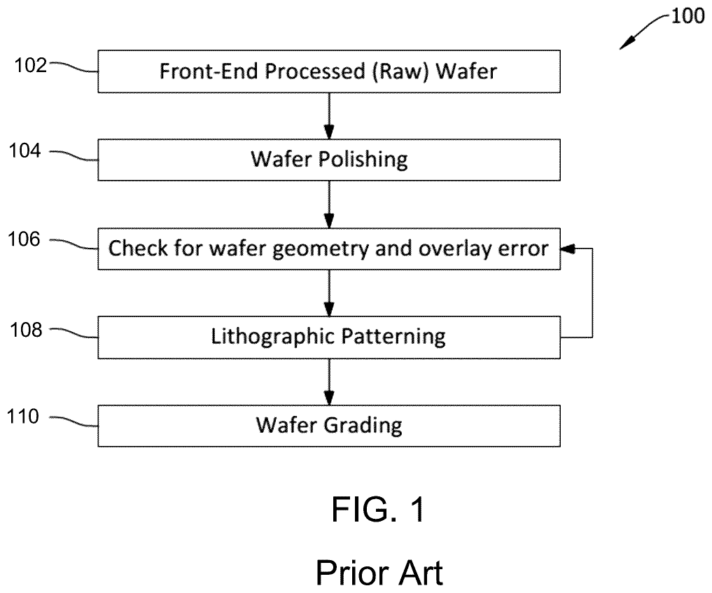

FIG. 1 is a flowchart of a process 100 for processing a wafer using a polished wafer geometry metric. At step 102, a front-end processed wafer is provided for further processing. As used herein, “front-end processed” is a wafer that has been processed by a front-end process tool, including for example, a wafer sliced from a single crystal ingot of semiconductor material (e.g., silicon). The front-end processed wafer may also have had one or both surfaces etched, lapped or grinded, and/or have had the edges rounded. Examples of front-end process tools include wire saws, lapping tools, grinding tools, beveling tools, and etching tools.

The surface condition of front-end processed wafers provided by step 102 is still relatively rough and generally not suitable for lithographic processing, which requires a particularly flat surface. At step 104, the front-end processed wafer is polished. The polishing operation at step 104 may be an intermediate polishing operation and/or a finish polishing operation. In an intermediate polishing operation, the front surface of the front-end processed wafer is polished to improve flatness and remove handling scratches. In a finish polishing operation, the front surface of the wafer is finish polished to remove fine or “micro” scratches from the front surface and to produce a highly reflective, damage-free front surface of the wafer. As used herein, “in-process” is a wafer that has a front surface that has been intermediate and/or finish polished and, optionally, has undergone one or more patterning processing steps as described below. After the polishing at step 104, and optionally after additional patterning processing steps, a high accuracy inspection tool (e.g., a WaferSight™ 2 or 2+ bare wafer geometry metrology system manufactured by KLA-Tencor Corporation) may be used to determine the shape and flatness of the in-process wafer, as well as other parameters such as Nanotopography. From these measurements, conventional metrics may be used at step 106 to predict overlay errors for at least the first patterning step.

At step 108, a series of patterning processing steps involving lithography and other chemical and/or mechanical processing (e.g., chemical mechanical polishing, etching, passivation, diffusion, etc.) are carried out to form integrated circuit(s) (“die”) on the wafer. Various layers which may include, for example, photo-masked resist patterns, oxide layers, and metal layers, are deposited on the wafer. Each layer formed on the surface may have non-uniform, intrinsic stress, resulting in elastic deformation (e.g., IPD) of the wafer shape. To mitigate the effect of overlay errors on product yield, steps 106 and 108 may be repeated in sequence, whereby in-process overlay errors are corrected by adjusting the lithographic tool. However, as design rules continue to shrink for lithographic patterns (such as below 10 nm), in-process control of overlay becomes more difficult. Non-correctable overlay errors occur where no corrective action can be taken by the lithographic tool. As a result, low back-end yield of quality wafers is realized at wafer grading step 110.

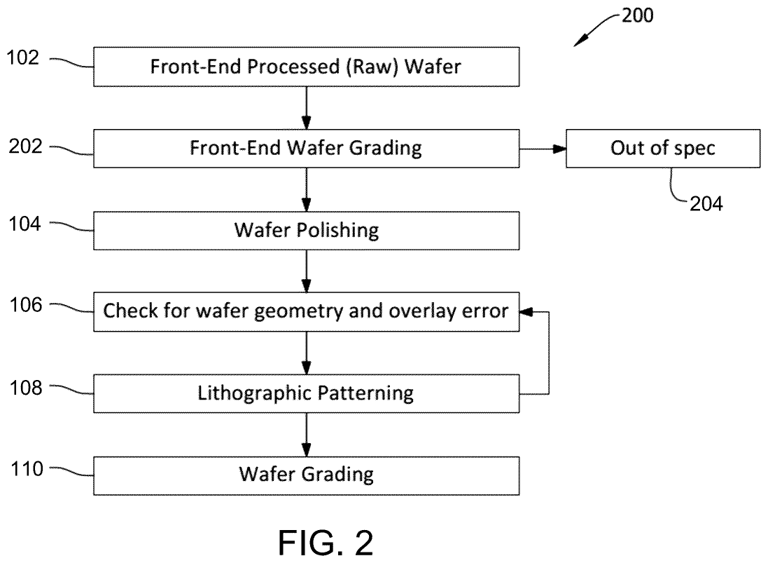

FIG. 2 is a flowchart of a process 200 for processing a wafer using a front-end processed wafer geometry metric. Example general process flow 200 shows processing semiconductor wafers with improved overlay and process control. A wafer is provided at step 102 discussed above in process 100. An additional process step 202 is included in process 200 where grading of the front-end processed wafer is performed before further processing and/or fabrication of the wafer. For example, the front-end wafer grading step 202 may take place before a wafer polishing step 104 and/or before patterning and layer formation step 108. At step 202, a wafer metric, such as a GAPI (Green Analytical Procedure Index) metric as discussed in more detail herein, is determined based on the shape and/or flatness of the front-end processed wafer. The wafer is then sorted at step 206 based on this metric. For example, the wafer may be determined to be outside a desired specification based on the metric and is discarded or identified for further front-end processing at step 206. If the wafer is determined to meet a desired specification, the wafer may be further processed starting, for example, at polishing step 104. The desired specification may be, for example, a tolerance level of predicted IPD (in-plane distortion) during wafer processing based on a correlated back-end yield.

One advantage of process 200 is that the wafer grading takes place before certain irreversible processing steps occur. Out of specification wafers sorted at step 204 may be salvaged by further processing using front-end tools to bring the wafer metric within the desired specification. For example, lapping or grinding processes may be repeated to adjust the shape and/or flatness of the wafer. Additionally, by identifying out of specification wafers early on in wafer processing, an improved back-end yield of processed wafers at wafer grading step 110 can be achieved. This increases the amount of quality grade dies that are eventually formed, and cuts costs associated with non-correctable overlay errors that occur during manufacturing. Also, because the wafers that are further processed have been vetted for predicted IPD, the need for in-process overlay control may be reduced or eliminated. In this regard, more efficient sequencing between overlay control at step 106 and wafer patterning at step 108 can be realized.

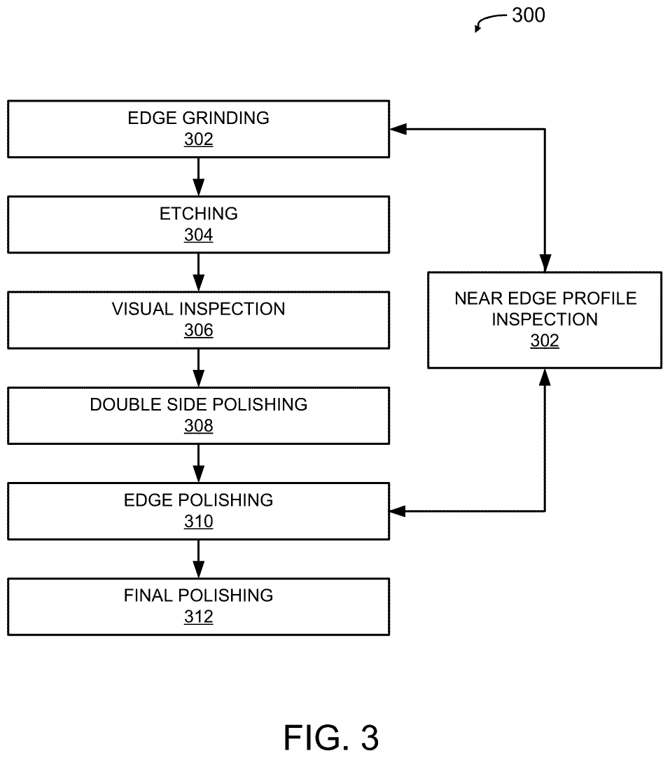

FIG. 3 is flowchart of a process 300 of wafer sampling to determine NER (near edge region) roundness.

Edge grinding 302 is a process used to remove the rough edges of a wafer and make it flat and smooth. Edge grinding 302 significantly lowers the likelihood of breakage in the remaining manufacturing steps and later when device manufacturers use the wafers. Silicon wafer etching processes 304 are used for removing oxide layers from silicon micro-electronic devices. They are generally acidic and involve the exposure of a sample to the etching solution.

Then a visual inspection 306 of the wafer occurs. In at least one embodiment, the visual inspection is performed by one or more sensors that visually analyze the etched wafer. The visual inspection 306 may cause the system to reject the wafer and/or modify one or more parameters of the double-sided polishing 308 and/or the edge polishing 310. If the wafer passes all inspections so far, then it is processed by final polishing 312.

Double-sided polishing 308 uses one or more polishing pads to polish both sides of the wafer. Then edge polishing 310 is used to improve cleanliness and lower breakage. The wafer edge shape profile is determined by edge grinding 302 and edge polishing 310 processes, for near edge shape profile which is much stronger related to edge polishing 310 process. Process 300 may be used to generate NER roundness data after edge grinding 302 or after edge polishing 310 to determine the wafer edge shape profile. More specifically, a near edge profile inspection 314 occurs in accordance with the disclosure made herein. The near edge profile inspection 314 uses statistical process control (SPC) sampling to select one or more wafers to inspect.

After edge grinding 302 or edge polishing 310 processes, the wafers may be sampled and by using 3D microscope (e.g., laser or white light interferometry) to measure the near edge height profiles (by front/backside and different angles). Then the NER algorithm described herein is used to output the best fitting circle radius and theta angle of near edge shape profile (transition zone arc) for process monitoring and control.

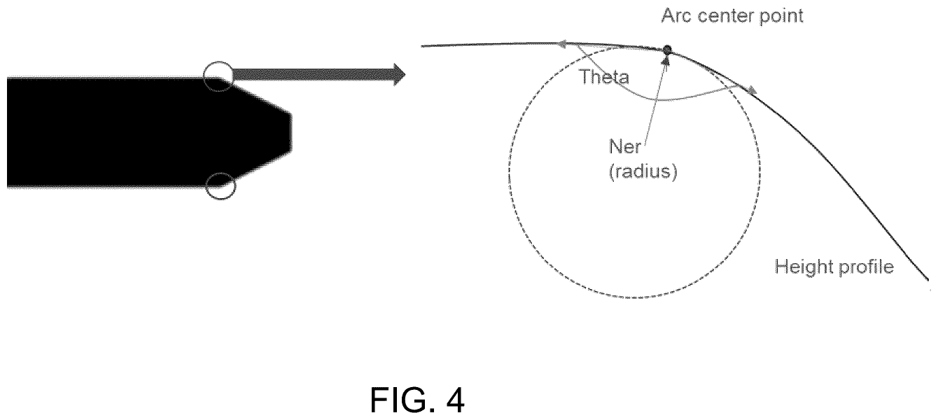

FIG. 4 illustrates the near edge transition zone and the NER roundness quantitative analysis method. In accordance with embodiments of the present disclosure, the roundness determination is made in a near edge region of the wafer, i.e., a “transition zone” between the edge region and the flat surface of the wafer. As shown in FIG. 4, the edge region is the most radially outward portion of the wafer which reduces in thickness according to the desired edge profile. This edge region is bordered by the rounded transition zone in which the wafer transitions to the wafer bulk (i.e., wafer surface). In some embodiments, the edge region has a radial width ranging from 25 μm to 750 μm. The radial width of the transition region may be 25 μm to 2 mm (e.g., 50 μm to 1 mm or 50 μm to 500 μm).

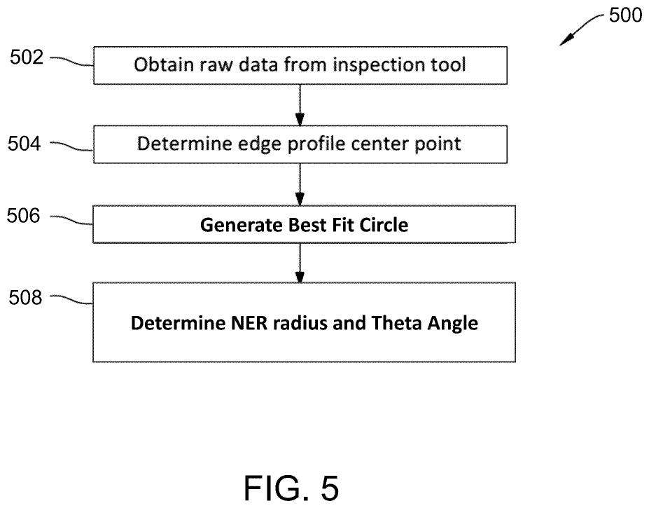

FIG. 5 illustrates a method 500 calculating NER values of the transition zone of a front-end processed wafer is shown. At step 502, measurement data of an edge profile of the front-end processed wafer is obtained. For example, the edge profile data may be obtained using commercial 3D microscopes such as by coherence scanning interferometric, confocal laser scanning, or laser scanning microscopes (such as those manufactured by Zygo, Olympus, or Keyence). The measured wafer may be in an unchucked (i.e., free-standing) state. At step 504, a simplification algorithm is used to convert the edge profile data into a simplified curve by reducing the set of points comprising the edge profile. At step 506, the best fit circle is generated and the NER radius and theta angle are determined in step 508.

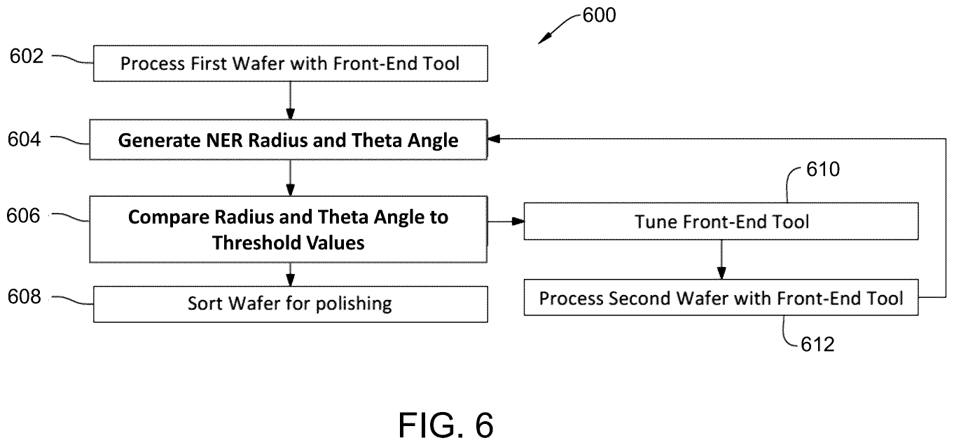

FIG. 6 illustrates a method 600 for determining a NER metric for a front-end processed wafer is described. NER values (e.g., radius and theta angle) may be used to adjust a front-end process tool. At step 602, a wafer is processed by a front-end process tool. For example, a wafer may be sliced from a single crystal ingot of semiconductor material (e.g., silicon) using a wire saw. The wafer may also be brought to a desired thickness using a front-end tool such as a lapping tool or a grinding tool.

At step 604, the NER radius and/or theta angle of the front-end processed (e.g., wire sawed, lapped and/or grinded) wafer is generated in accordance with the present disclosure. At step 606, the NER value(s) is compared to a predetermined threshold value. The predetermined threshold value may be based on historical data which correlates the NER value to a back-end yield percentage. For example, the threshold may be set to a NER value which correlates with a back-end yield percentage of greater than 50%. If the NER value is within the predetermined threshold (e.g., less than or equal to the threshold NER value), then the front-end processed wafer is sorted for polishing at step 608.

If the NER value is not within the predetermined threshold (e.g., is greater than the threshold NER value), then the wafer may not be sorted for polishing. At step 610, one or more of the front-end tools may be tuned (e.g., adjusted and/or modified) after determining the NER value of the front-end processed wafer is not within the predetermined threshold. The one or more front-end process tools may be tuned 510 based on at least one of the NER profiles of the wafer having a NER value outside the predetermined threshold. After the front-end tool is tuned 510, the front-end tool is then used to process 512 the next wafer.

One advantage of the process 600 is that adjustments and/or modifications of the front-end tool may be made more quickly and efficiently using a metric early on in the wafering process (e.g., before polishing). Existing metrics used to predict wafer deformation during fabrication require the wafer be polished in order to obtain high quality shape and/or flatness data of the wafer. Process anomalies in front-end tools (e.g., wire saw, lapping tool, or grinding tool) therefore cannot be identified until after the front-end processed wafer is polished. Generally, significant time passes (hours, days, weeks) between the front-end processing and the polishing of a given wafer. In the meantime, a large volume of wafers may be processed by the front-end tool(s), and therefore are at risk of surface variations and unacceptable NER values that will not be identified until the initial wafer is polished and scanned. In this regard, process 500 provides a significant improvement by providing early detection of process anomalies in the front-end process which can be fixed by tuning the front-end tool(s) and thereby impact fewer wafers.

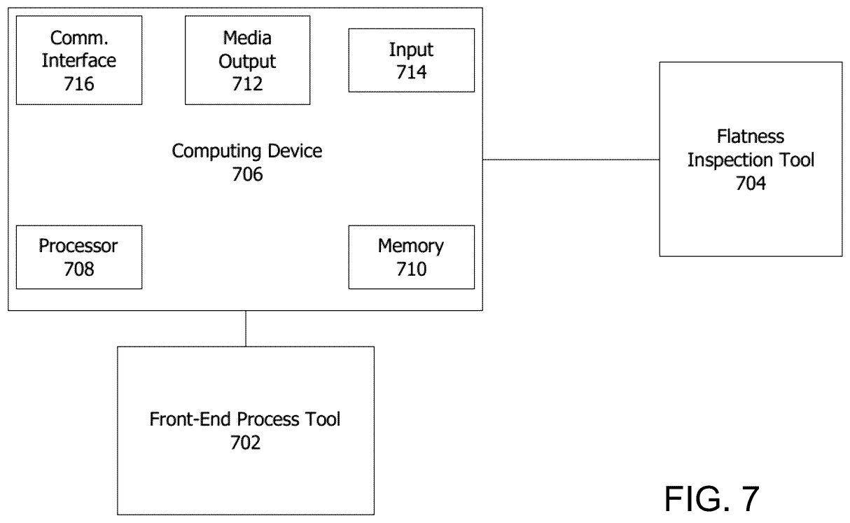

FIG. 7 illustrates an example block diagram of a system 700 for processing a wafer using a front-end processed wafer geometry metric in accordance with the present disclosure is shown. System 700 includes a front-end process tool 702, a flatness inspection tool 704 (e.g., 3D microscope), and a computing device 706 which is connected or communicatively coupled to the front-end process tool 702 and/or the flatness inspection tool 704.

Front-end process tool 702 may be any machining tool configured to provide a front-end processed wafer in accordance with the present disclosure. In an example embodiment, front-end process tool 702 is a wire saw. In other embodiments, front-end process tool 702 may be a grinding tool, a lapping tool, a beveling tool, or an etching tool. Flatness inspection tool 704 is a 3D microscope that generates the transition zone to obtain the near-edge profile.

Computing device 706 includes a processor 708 for executing instructions. In some embodiments, executable instructions are stored in a memory area 710. The processor 708 may include one or more processing units (e.g., in a multi-core configuration). The memory area 710 is any device allowing information such as executable instructions and/or data to be stored and retrieved. The memory area 710 may include one or more computer readable storage devices or other computer readable media, including transitory and non-transitory computer readable media.

Computing device 706 also includes at least one media output component 712 for presenting information to a user (e.g., a wafer end user, quality control personnel, etc.). The media output component 712 is any component capable of conveying information to the user. In some embodiments, the media output component 712 includes an output adapter such as a video adapter and/or an audio adapter. An output adapter is operatively connected to the processor 708 and operatively connectable to an output device such as a display device (e.g., a liquid crystal display (LCD), organic light emitting diode (OLED) display, cathode ray tube (CRT), or “electronic ink” display) or an audio output device (e.g., a speaker or headphones). In some embodiments, at least one such display device and/or audio device is included in the media output component 712.

In some embodiments, computing device 706 includes an input device 714 for receiving input from the user. The input device 714 may include, for example, a keyboard, a pointing device, a mouse, a stylus, a touch sensitive panel (e.g., a touch pad or a touch screen), a gyroscope, an accelerometer, a position detector, or an audio input device. A single component such as a touch screen may function as both an output device of the media output component 712 and the input device 714.

Computing device 706 may also include a communication interface 716, which may be communicatively connected to one or more remote devices. The communication interface 716 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

Stored in the memory area 710 are, for example, processor-executable instructions for receiving and processing input from flatness inspection tool 704 and modifying front-end process tool 702 based on the processed input received from flatness inspection tool 704. The memory area 710 may include, but is not limited to, any computer-operated hardware suitable for storing and/or retrieving processor-executable instructions and/or data. The memory area 710 may include random access memory (RAM) such as dynamic RAM (DRAM) or static RAM (SRAM), read-only memory (ROM), erasable programmable read-only memory (EPROM), electrically erasable programmable read-only memory (EEPROM), and nonvolatile RAM (NVRAM). Further, the memory area 710 may include multiple storage units such as hard disks or solid state disks in a redundant array of inexpensive disks (RAID) configuration. The memory area 710 may include a storage area network (SAN) and/or a network attached storage (NAS) system. In some embodiments, the memory area 710 includes memory that is integrated in computing device 706. For example, computing device 706 may include one or more hard disk drives as the memory area 710. The memory area 710 may also include memory that is external to computing device 706 and may be accessed by a plurality of computing devices. The above memory types are examples only, and are thus not limiting as to the types of memory usable for storage of processor-executable instructions and/or data.

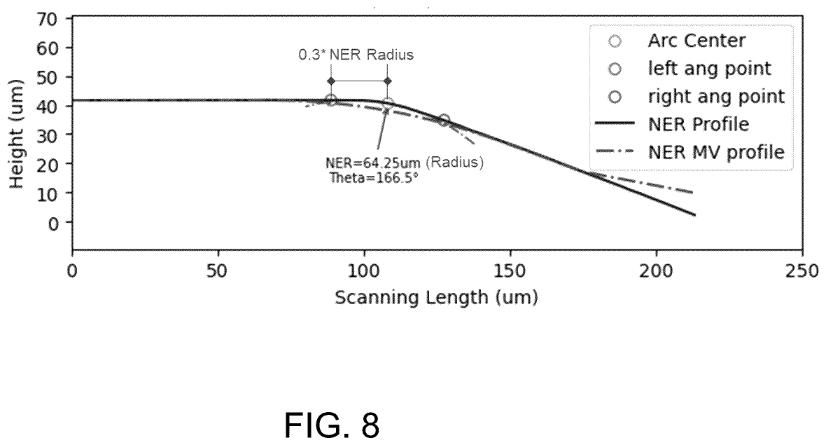

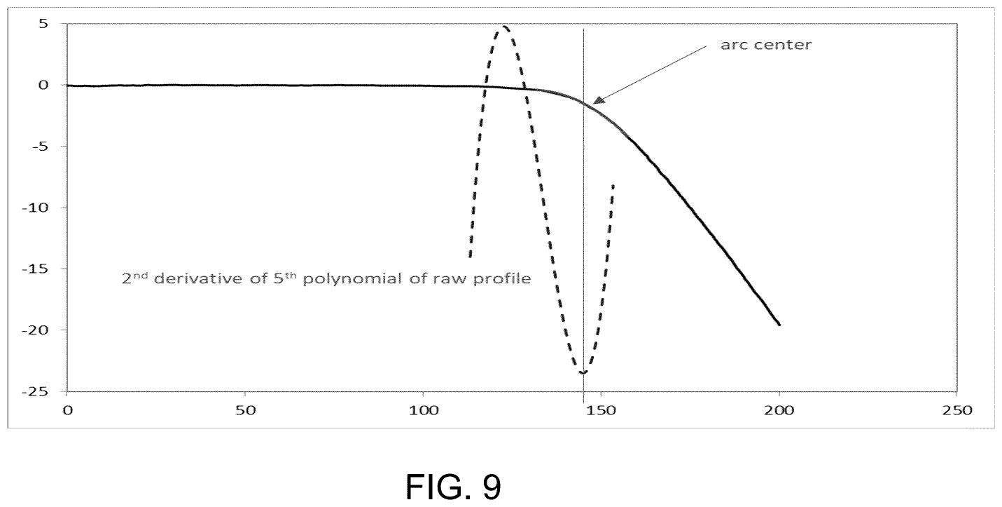

FIG. 8 illustrates a graph of the moving average height profile with the arc center being the max height between raw and moving average profiles. FIG. 9 shows the 2nd derivative of the 5th polynomial fitting profile.

The method for determining near edge roundness is shown in FIGS. 8 and 9. To determine NER, the near edge height profile is determined (e.g., by front by front/backside and different angles as). The near edge height profile may be determined by a 3D microscope (e.g., laser or white light interferometry). A radius of a circle fit to the near edge transition zone arc is determined. The transition zone is the zone radially inward to the edge profile of the wafer. The theta angle of the near edge shape profile is then determined. The near edge radius may be determined by an algorithm as further described herein.

In some embodiments, the near edge height profile is determined by a 3D microscope. For example, the 3D microscope may have a scanning length across the near edge zone of 200 μm or more. The profile may be smoothed by using a moving average to reduce noise. For example, a 3 to 5 μm moving average length may be calculated.

Once the near edge height profile is determined, the arc center (e.g., turning point) of the transition zone (near edge shape profile) is determined. The arc center may be determined by (1) the maximum distance between the raw profile and the moving average profile or (2) the profile curvature. For example, the maximum distance method (FIG. 4) may use a 25 to 50 μm length. Profile trimming is based on the arc center+/−a distance. This distance (e.g., x x<=100˜150 μm) is the arc center to the beginning/end of the profiles (i.e., the same length for arc center to the left and right). The arc center is the maximum height difference between the raw and the moving average profile (position of max(raw−mv)).

In some embodiments, the profile curvature is determined. For example and as shown in FIG. 9, the curvature may be calculated by taking the 2nd derivative of the 5th polynomial fitting of the raw profile. The arc center is the minimum curvature position with profile trimming as mentioned above (solid line shown is the raw wafer near edge shape profile).

The best fit circle takes the arc center (as determined by method (1) or (2) above)+/−a distance (e.g., 8-15 μm). The best fit circle may be determined by an algorithm such as taubinSVD, hyperSVD, standardLSQ algorithm (see https://pypi.org/project/circle-fit/which is incorporated herein for all relevant and consistent purposes).

Theta angle may be determined from three points-the arc center point, left ang point and right ang point (shown in FIG. 8). The left and right ang points are the arc center+/−0.25˜0.3*fitting radius (by x-axis).

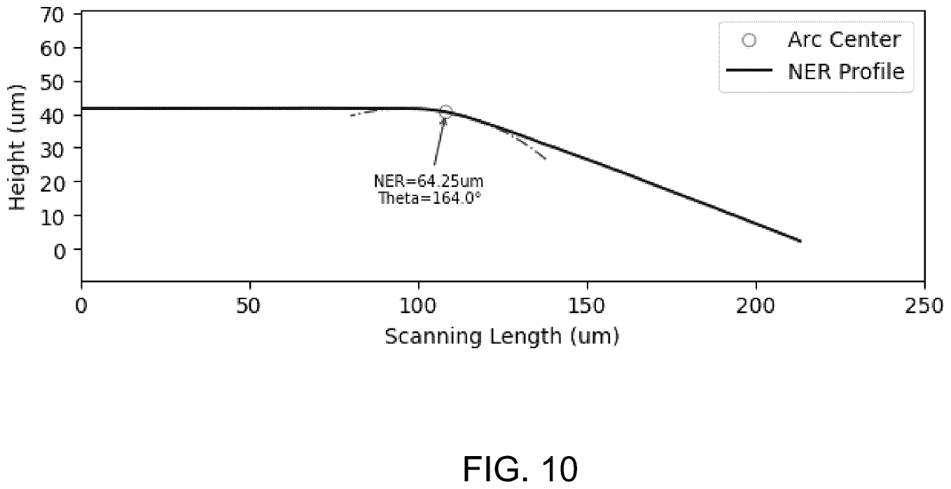

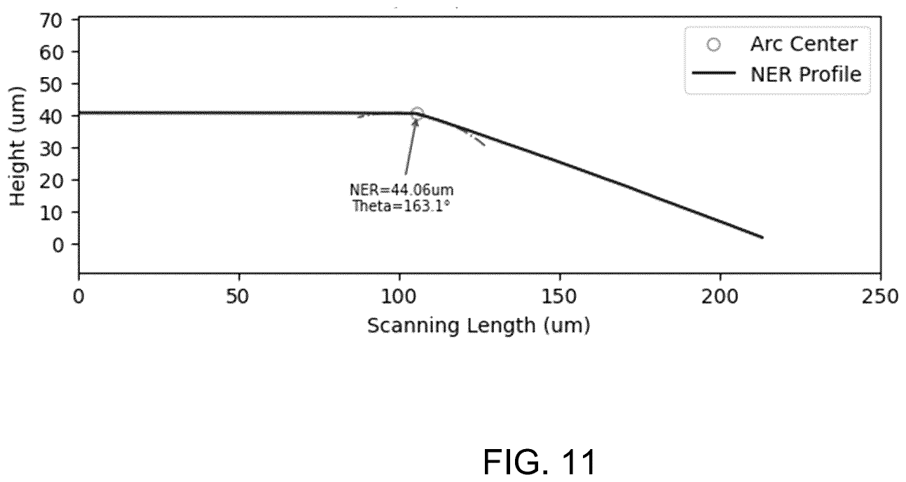

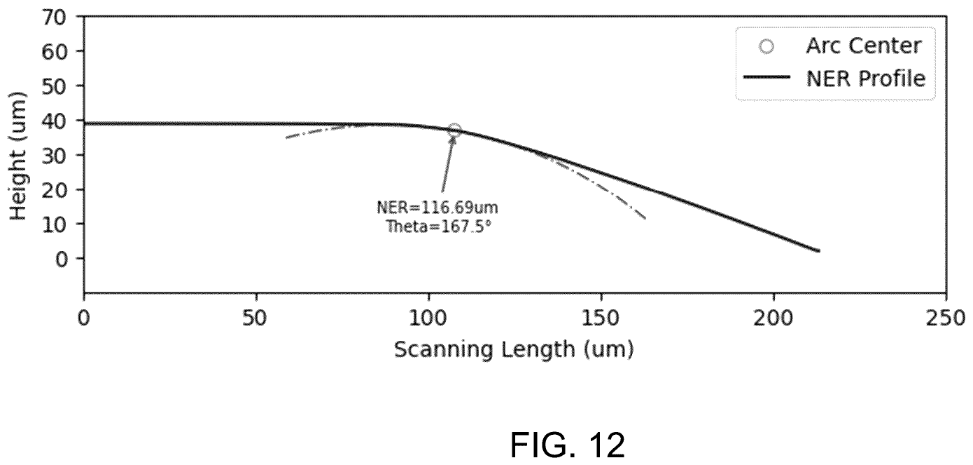

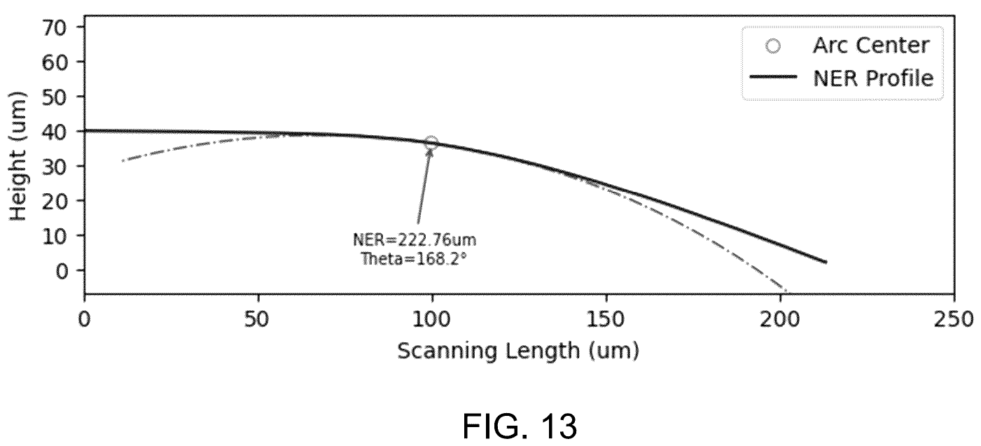

FIGS. 10-13 are example near edge profiles showing NER radius and theta angle. FIG. 10 illustrates a NER profile produced by the methods described herein. FIG. 11 illustrates a sharp transition between top surface to bevel and a small NER radius and theta. FIG. 12 illustrates median transition with middle NER radius and theta. FIG. 13 illustrates a smooth transition with large NER radius and theta.

In some embodiments, a computer device 706 for analyzing a processed product is provided. The computer device 706 includes at least one processor 708 in communication with at least one memory device 710. The computer device 706 receives scan data of a first inspection of a first product being assembled after the first product has been processed by a tool 702. The scan data is provided by a flatness inspection tool 704. The computer device 706 determines an edge profile for the product based upon the scan data. The computer device 706 determines a center point for the edge profile. The computer device 706 generates a best fit circle based upon the edge profile and the center point. The computer device 706 calculates a NER (near edge region) radius for the first product based upon the best fit circle. The computer device 706 adjusts operation of the tool 702 based upon the NER radius.

In some further embodiments, the computer device 706 compares the NER radius to one or more thresholds. The computer device 706 approves or denies the first product for being further processed based upon the comparison. The computer device 706 adjusts operation of the tool 702 based upon the comparison.

In further embodiments, the computer device 706 calculates a theta angle for the first product based upon the best fit circle and the center point. The computer device 706 determines a right ang point and a left ang point for the edge profile. The computer device 706 calculates the theta angle for the product based upon the right ang point, the left ang point, and the center point of the edge profile. The computer device 706 compares the NER radius and the theta angle to one or more thresholds. The computer device 706 approves or denies the first product for being further processed based upon the comparison. The computer device 706 adjusts operation of the tool 702 based upon the comparison.

In still further embodiments, the tool 702 is one of a wire saw, a lapping tool, and a grinding tool. The first product is a silicon wafer. The scan data is received from a 3D microscope.

In additional embodiments, the computer device 706 simplifies the edge profile by reducing a number of points in the edge profile.

In other embodiments, the computer device 706 smooths the edge profile by using a moving average to reduce noise

### Additional Considerations

Example embodiments of compressor systems and methods, such as refrigerant compressors, are described above in detail. The systems and methods are not limited to the specific embodiments described herein, but rather, components of the system and methods may be used independently and separately from other components described herein. For example, the cooling circuits described herein may be used in compressors other than centrifugal compressors, including, for example and without limitation, scroll compressors, rotary compressors, and reciprocating compressors.

Example embodiments of compressor systems and methods, such as refrigerant compressors, are described above in detail. The systems and methods are not limited to the specific embodiments described herein, but rather, components of the system and methods may be used independently and separately from other components described herein. For example, the cooling circuits described herein may be used in compressors other than centrifugal compressors, including, for example and without limitation, scroll compressors, rotary compressors, and reciprocating compressors.

As will be appreciated based upon the foregoing specification, the above-described embodiments of the disclosure may be implemented using computer programming or engineering techniques including computer software, firmware, hardware or any combination or subset thereof. Any such resulting program, having computer-readable code means, may be embodied or provided within one or more computer-readable media, thereby making a computer program product, i.e., an article of manufacture, according to the discussed embodiments of the disclosure. The computer-readable media may be, for example, but is not limited to, a fixed (hard) drive, diskette, optical disk, magnetic tape, semiconductor memory such as read-only memory (ROM), and/or any transmitting/receiving medium, such as the Internet or other communication network or link. The article of manufacture containing the computer code may be made and/or used by executing the code directly from one medium, by copying the code from one medium to another medium, or by transmitting the code over a network.

These computer programs (also known as programs, software, software applications, “apps,” or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only and are thus not intended to limit in any way the definition and/or meaning of the term “processor.”

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

As used herein, the term “database” can refer to either a body of data, a relational database management system (RDBMS), or to both. As used herein, a database can include any collection of data including hierarchical databases, relational databases, flat file databases, object-relational databases, object-oriented databases, and any other structured collection of records or data that is stored in a computer system. The above examples are example only, and thus are not intended to limit in any way the definition and/or meaning of the term database. Examples of RDBMS' include, but are not limited to including, Oracle® Database, MySQL, IBM® DB2, Microsoft® SQL Server, Sybase®, and PostgreSQL. However, any database can be used that enables the systems and methods described herein. (Oracle is a registered trademark of Oracle Corporation, Redwood Shores, California; IBM is a registered trademark of International Business Machines Corporation, Armonk, New York; Microsoft is a registered trademark of Microsoft Corporation, Redmond, Washington; and Sybase is a registered trademark of Sybase, Dublin, California.)

In another example, a computer program is embodied on a computer-readable medium. In an example, the system is executed on a single computer system, without requiring a connection to a server computer. In a further example, the system is being run in a Windows® environment (Windows is a registered trademark of Microsoft Corporation, Redmond, Washington). In yet another example, the system is run on a mainframe environment and a UNIX® server environment (UNIX is a registered trademark of X/Open Company Limited located in Reading, Berkshire, United Kingdom). In a further example, the system is run on an iOS® environment (iOS is a registered trademark of Cisco Systems, Inc. located in San Jose, CA). In yet a further example, the system is run on a Mac OS® environment (Mac OS is a registered trademark of Apple Inc. located in Cupertino, CA). In still yet a further example, the system is run on Android® OS (Android is a registered trademark of Google, Inc. of Mountain View, CA). In another example, the system is run on Linux® OS (Linux is a registered trademark of Linus Torvalds of Boston, MA). The application is flexible and designed to run in various different environments without compromising any major functionality.

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

As used herein, the terms “software” and “firmware” are interchangeable and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

Furthermore, as used herein, the term “real-time” refers to at least one of the time of occurrence of the associated events, the time of measurement and collection of predetermined data, the time to process the data, and the time of a system response to the events and the environment. In the examples described herein, these activities and events occur substantially instantaneously.

In some embodiments, the system includes multiple components distributed among a plurality of computer devices. One or more components may be in the form of computer-executable instructions embodied in a computer-readable medium. The systems and processes are not limited to the specific embodiments described herein. In addition, components of each system and each process can be practiced independent and separate from other components and processes described herein. Each component and process can also be used in combination with other assembly packages and processes. The present embodiments may enhance the functionality and functioning of computers and/or computer systems.

The computer-implemented methods discussed herein can include additional, less, or alternate actions, including those discussed elsewhere herein. The methods can be implemented via one or more local or remote processors, transceivers, servers, and/or sensors (such as processors, transceivers, servers, and/or sensors mounted on vehicles or mobile devices, or associated with smart infrastructure or remote servers), and/or via computer-executable instructions stored on non-transitory computer-readable media or medium. Additionally, the computer systems discussed herein can include additional, less, or alternate functionality, including that discussed elsewhere herein. The computer systems discussed herein can include or be implemented via computer-executable instructions stored on non-transitory computer-readable media or medium.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein can be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

The patent claims at the end of this document are not intended to be construed under 35 U.S.C. § 112 (f) unless traditional means-plus-function language is expressly recited, such as “means for” or “step for” language being expressly recited in the claim(s).

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A computer device for analyzing a processed product comprising at least one processor in communication with at least one memory device, wherein the at least one processor is programmed to:
receive scan data of a first inspection of a first product being assembled after the first product has been processed by a tool;
determine an edge profile for the product based upon the scan data;
determine a center point for the edge profile;
generate a best fit circle based upon the edge profile and the center point;
calculate a NER radius for the first product based upon the best fit circle; and
adjust operation of the tool based upon the NER radius.

2. The computer device of claim 1, wherein the at least one processor is further programmed to compare the NER radius to one or more thresholds.

3. The computer device of claim 2, wherein the at least one processor is further programmed to approve or deny the first product for being further processed based upon the comparison.

4. The computer device of claim 2, wherein the at least one processor is further programmed to adjust operation of the tool based upon the comparison.

5. The computer device of claim 1, wherein the at least one processor is further programmed to calculate a theta angle for the first product based upon the best fit circle and the center point.

6. The computer device of claim 5, wherein the at least one processor is further programmed to:
determine a right ang point and a left ang point for the edge profile; and
calculate the theta angle for the product based upon the right ang point, the left ang point, and the center point of the edge profile.

7. The computer device of claim 5, wherein the at least one processor is further programmed to compare the NER radius and the theta angle to one or more thresholds.

8. The computer device of claim 7, wherein the at least one processor is further programmed to approve or deny the first product for being further processed based upon the comparison.

9. The computer device of claim 7, wherein the at least one processor is further programmed to adjust operation of the tool based upon the comparison.

10. The computer device of claim 1, wherein the tool is one of a wire saw, a lapping tool, and a grinding tool.

11. The computer device of claim 1, wherein the first product is a silicon wafer.

12. The computer device of claim 1, wherein the scan data is received from a 3D microscope.

13. The computer device of claim 1, wherein the at least one processor is further programmed to simplify the edge profile by reducing a number of points in the edge profile.

14. The computer device of claim 1, wherein the at least one processor is further programmed to smooth the edge profile by using a moving average to reduce noise.

15. A method for analyzing a processed product, the method is performed by a computing device comprising at least one processor in communication with at least one memory device, wherein the method comprises:
receiving scan data of a first inspection of a first product being assembled after the first product has been processed by a tool;
determining an edge profile for the product based upon the scan data;
determining a center point for the edge profile;
generating a best fit circle based upon the edge profile and the center point;
calculating a NER radius for the first product based upon the best fit circle; and
adjusting operation of the tool based upon the NER radius.

16. The method of claim 15 further comprising:
comparing the NER radius to one or more thresholds;
approving or denying the first product for being further processed based upon the comparison; and
adjusting operation of the tool based upon the comparison.

17. The method of claim 15 further comprising:
calculating a theta angle for the first product based upon the best fit circle and the center point;
determining a right ang point and a left ang point for the edge profile; and
calculating the theta angle for the product based upon the right ang point, the left ang point, and the center point of the edge profile.

18. The method of claim 17 further comprising:
comparing the NER radius and the theta angle to one or more thresholds;
approving or denying the first product for being further processed based upon the comparison; and
adjusting operation of the tool based upon the comparison.

19. The method of claim 15, wherein the tool is one of a wire saw, a lapping tool, and a grinding tool, wherein the first product is a silicon wafer, and wherein the scan data is received from a 3D microscope.

20. The method of claim 15 further comprising smoothing the edge profile by using a moving average to reduce noise.
